(19) United States
(12) Patent Application Publication
(10) Pub. No.: US 2015/0155331 A1
(43) Pub. Date: Jun. 4, 2015

(54) METHOD OF COLLECTIVE MANUFACTURE OF LEDS AND STRUCTURE FOR COLLECTIVE MANUFACTURE OF LEDS

(71) Applicant: Soitec, Bernin (FR)

(72) Inventor: Pascal Guenard, Froges (FR)

(21) Appl. No.: 14/409,650

(22) PCT Filed: Jun. 18, 2013
(86) PCT No.: PCT/EP2013/062658

§ 371 Date: Dec. 19, 2014

(30) Foreign Application Priority Data
Jun. 22, 2012 (FR) 1255931
Jun. 22, 2012 (FR) 1255934

(51) Int. Cl. H01L 27/15; H01L 33/12; H01L 33/00; H01L 33/62

(52) U.S. Cl. CPC H01L 27/153; H01L 33/62; H01L 33/12; H01L 33/005; H01L 2933/0066

(57) ABSTRACT

The disclosure relates to a method of collective manufacturing of light-emitting diode (LED) devices comprising formation of elemental structures, each comprising an n-type layer, an active layer and a p-type layer, the method comprising: —reduction of the lateral dimensions of part of each elemental LED structure; —formation of a portion of insulating material on the sides of the elemental structures; —formation of n-type electrical contact pads and p-type electrical contact pads; —deposition of a conductive material layer; on the elemental structures and polishing of the conductive material layer; and—bonding by molecular adhesion of a second substrate on the polished surface of the structure.

### CROSS-REFERENCE TO RELATED APPLICATIONS

This application is a national phase entry under 35 U.S.C. §371 of International Patent Application PCT/EP2013/062658, filed Jun. 18, 2013, designating the United States of America and published in English as International Patent Publication WO 2013/189949 A1 on Dec. 27, 2013, which claims the benefit under Article 8 of the Patent Cooperation Treaty and under 35 U.S.C. §119(e) to French Patent Application Serial Nos. 1255931 and 1255934, both filed Jun. 22, 2012, the disclosure of each of which is hereby incorporated herein in its entirety by this reference.

### TECHNICAL FIELD

This disclosure relates to the manufacture of light-emitting diodes (LEDs).

### BACKGROUND

LEDs are generally manufactured from elemental structures corresponding to a stack of layers comprising at least one n-type layer or region, a p-type layer or region and an active layer disposed between the n-type and p-type layers. These elemental LED structures can be formed from the same growth substrate on which a stack of the layers described above is formed by epitaxial growth, portions of this stack then being cut out of the substrate to each form an elemental LED structure.

However, other LED manufacturing operations, such as wiring of the LED by formation of n- and p-type contact pads or disassembly/removal of the growth support notably required to carry out treatments in the case of high-intensity LEDs, are carried out, all or in part, on the level of each LED individually, meaning that the elemental structures are separate from each other and that one structure at a time is thus dealt with.

The same is true for operations involved in the assembly of LEDs on a mechanical support and operations of deposition of a light-converting material (“phosphorus”), which are carried out individually for each LED.

Although carrying out these operations individually allows good control of the precision of the LED manufacturing process, it multiplies the number of operations by the number of LEDs to be manufactured and, consequently, increases LED manufacturing costs.

### BRIEF SUMMARY

The object of this disclosure is to notably remedy the disadvantages mentioned above by allowing a collective manufacture of LEDs.

This aim is achieved with a method of collective manufacturing of light-emitting diode (LED) devices comprising formation on a surface of a first substrate of a plurality of elemental LED structures, each comprising at least one n-type layer, an active layer and a p-type layer, the elemental LED structures being spaced apart from each other on the first substrate by trenches, the method further comprising:
reduction of the lateral dimensions of the p-type layer, the active layer and a first part of the n-type layer in contact with the active layer, the n-type layer having a second part with lateral dimensions larger than the first part of the n-type layer;
deposition of an insulating material layer on at least each elemental structure;
formation of a portion of insulating material on the sides of the p-type layer, the active layer and the first part of the n-type layer;
formation of n-type electrical contact pads on at least the whole of the second part of the exposed n-type layer;
formation of p-type electrical contact pads before or after the lateral dimension reduction step;
deposition of a conductive material layer on the whole of the surface of the first substrate comprising the elemental LED structures and polishing of the conductive material layer, polishing being carried out until reaching at least the part of the insulating material layer present between the p- and n-type electrical contact pads so as to form a structure comprising individual portions of conductive material layer, each individual portion being in contact with one or more n-type electrical contact pads; and
bonding by molecular adhesion of a second substrate on the polished surface of the structure.

Thus, the inventive method makes it possible to collectively form n-type contact pads and p-type contact pads for the whole of the elemental structures present on the substrate. The number of operations required to form the contact pads is here considerably fewer in relation to the prior art wherein contact pads are formed independently on each elemental structure. One thus has a substrate or plate comprising a plurality of wired elemental structures that can be cut out individually or as a group to form LED devices.

The disclosure advantageously makes it possible to form n- and p-type contact pads and to assemble the substrate comprising the elemental LED structures with a transfer substrate, all in a minimum of steps, thus making it possible to reduce costs and production times.

In a particular embodiment, the n- and p-type contact pads are prepared simultaneously during the same step in which a metal layer is deposited on the whole of the elemental structures.

In a particular embodiment, the insulating material layer is further deposited in a part of the trenches present between the elemental LED structures, the trenches free of insulating material, delimiting cutting zones around the elemental LED structures.

In a particular embodiment, each elemental LED structure is formed on an island of relaxed or partially relaxed material.

The relaxed or partially relaxed material is InGaN, for example.

In a particular embodiment, the method includes, after bonding of the second substrate, removal of the first substrate.

The initial substrate, notably making it possible to free the light-emitting surface of the LED devices, is removed in a single operation for the whole of the elemental structures. In certain cases, the substrate once removed can also be recycled and used again one or more times.

The method can further include deposition of a light-converting material layer on the surface of the elemental LED structures exposed after removal of the first substrate.

One thus has a structure from which can be cut out LED devices, each formed of one or more wired elemental structures, provided with a final substrate and covered with a light-converting layer.

In a particular embodiment, the method includes formation of microstructures on the surface of the elemental LED structures exposed after removal of the first substrate.

One thus has a structure from which LED devices can be cut out, each formed of one or more wired elemental structures, provided with a final substrate, and microstructures notably making it possible to confer particular optical properties on the LED devices.

In a particular embodiment, the second substrate comprises a plurality of electrical contact pads on its bonding surface, disposed with positions of alignment with the individual portions of the conductive material layer or with the p-type contact pads.

The LED devices can thus be powered and controlled from the second substrate.

In a particular embodiment, formation of n-type contact pads comprises deposition of a conductive material layer of determined thickness on the whole of the surface of the first substrate comprising the elemental LED structures.

In a particular embodiment, the method further includes, after deposition of the conductive material layer, directive etching of the conductive material layer so as to allow portions of the conductive material layer to remain on the lateral walls of the elemental structures, the portions forming the n-type contact pads.

In a particular embodiment, the method includes, after the selective (or directive) etching step, formation of openings at a limited depth in the p-type layer of each elemental LED structure and filling of these openings with a conductive material so as to form a p-type contact pad.

Correspondingly, the disclosure relates to a structure for the collective manufacture of light-emitting diode (LED) devices comprising a first substrate including a plurality of elemental LED structures on a surface, each comprising at least one n-type layer, an active layer and a p-type layer, the elemental structures being spaced apart from each other on the first substrate by trenches, each elemental LED structure comprising:
a first part comprising the p-type layer, the active layer and a first part of the n-type layer in contact with the active layer and a second part comprising a second part of the n-type layer, the first part of each elemental LED structure having lateral dimensions less than the second part of each elemental LED structure;
a part of insulating material on the sides of the p-type layer, the active layer and the first part of the n-type layer;
an n-type electrical contact pad on at least the whole of the second part of the exposed n-type layer; and
p-type electrical contact pads;
the structure further comprising, on its side opposite that comprising the first substrate, a planar surface comprising individual portions of conductive material, each respectively in contact with an n-type electrical contact pad, the individual portions of the layers of conductive material being separated by portions of the insulating material layer, and
a second substrate (50) being bonded on the planar surface of the structure.

In a particular embodiment, the second substrate comprises a series of contact pads on its side bonded to the structure and separated from each other by portions of insulating material,

the pads of the series of contact pads being connected with the n- and p-type electrical contact pads of the elemental structures.

In a particular embodiment, the structure further comprises a light-converting material layer on the n-type layer of the elemental LED structures.

In a particular embodiment, the structure further comprises microstructures present on the n-type layer of the elemental LED structures.

### BRIEF DESCRIPTION OF THE FIGURES

FIGS. 1A to 10 are schematic perspective and cross-sectional views showing the collective manufacture of LED devices in accordance with an embodiment of the disclosure;

FIGS. 2A and 2B are flow diagrams of the steps implemented in FIGS. 1A to 1O;

FIGS. 3A to 3E are schematic perspective and cross-sectional views showing a variant embodiment of n-type contact pads in accordance with an embodiment of the disclosure;

FIG. 4 is a flow diagram of the steps implemented in FIGS. 3A to 3E;

FIGS. 5A to 5E are schematic perspective and cross-sectional views showing a variant embodiment of p-type contact pads in accordance with an embodiment of the disclosure;

FIG. 6 is a flow diagram of the steps implemented in FIGS. 5A to 5E;

FIGS. 7A to 7C are schematic perspective and cross-sectional views showing a variant embodiment of p-type contact pads in accordance with an embodiment of the disclosure; and

FIG. 8 is a flow diagram of the steps implemented in FIGS. 7A to 7C.

### DETAILED DESCRIPTION

This disclosure applies to the collective manufacture of light-emitting diode (LED) devices. As explained in detail below, the disclosure allows the collective manufacture of LED devices on a plate, each comprising at least one or more elemental LED structures that, at different stages of the process, are further provided with one or more of the following elements:
p-type contacts,
n-type contacts,
a final substrate provided with vertical electronic connections (vias) for access to the contacts, the final substrate being further able to be provided with electronic circuits,
a light-converting material layer,
microstructures, in particular, optical microstructures.

All of the elements mentioned above can be prepared collectively as in the example described below, i.e., during the same operations carried out on the whole of the elemental LED structures present on the plate. However, if need be, the LED devices can be cut out at an intermediate stage of the collective manufacturing method, for example, after formation of the p- and n-type contacts, and then processed individually in subsequent manufacturing steps. According to needs, in particular, in terms of light intensity, an LED device cut from the plate will be able to include several elemental LED structures connected in series or in parallel.

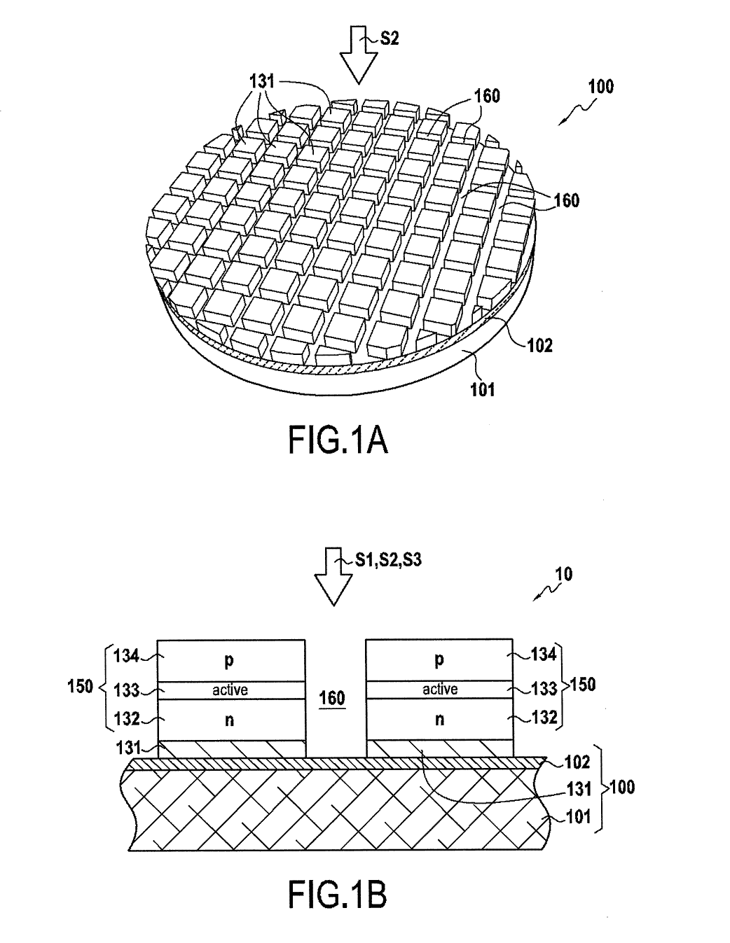

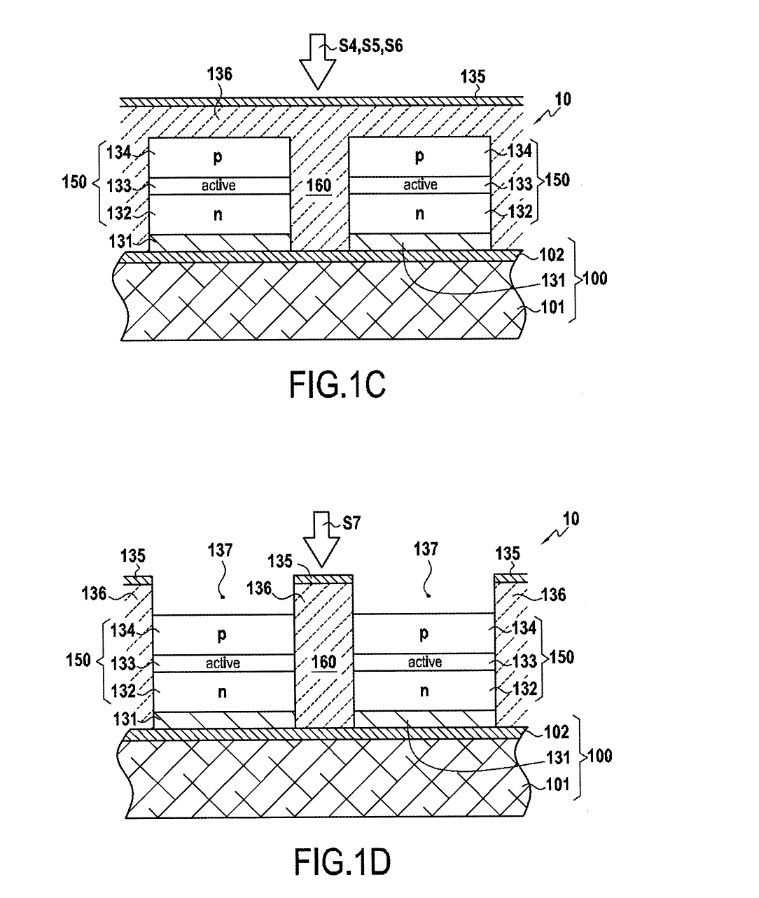

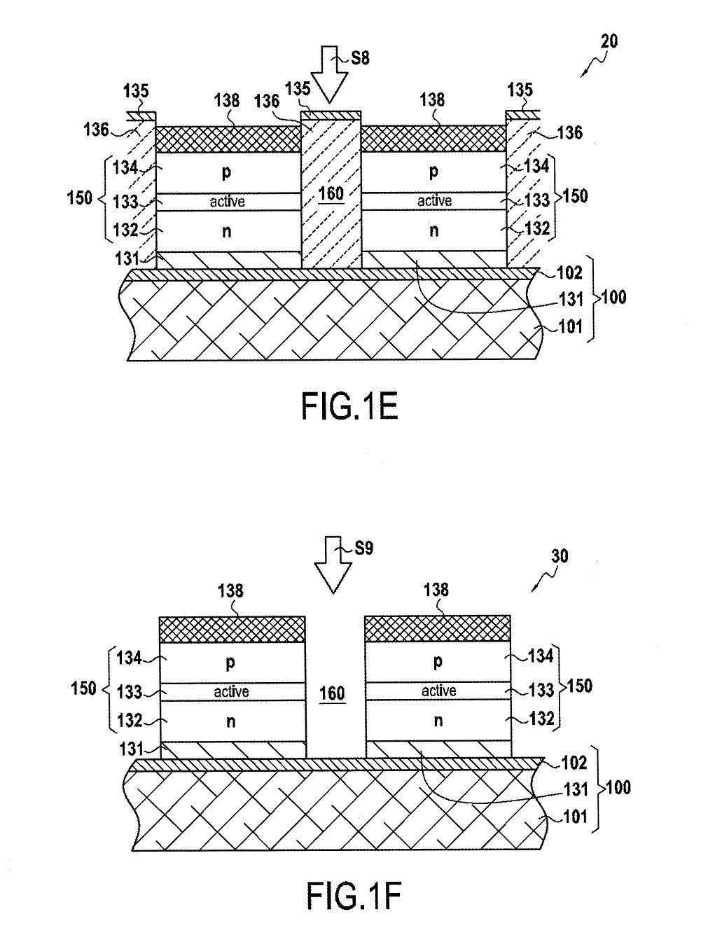

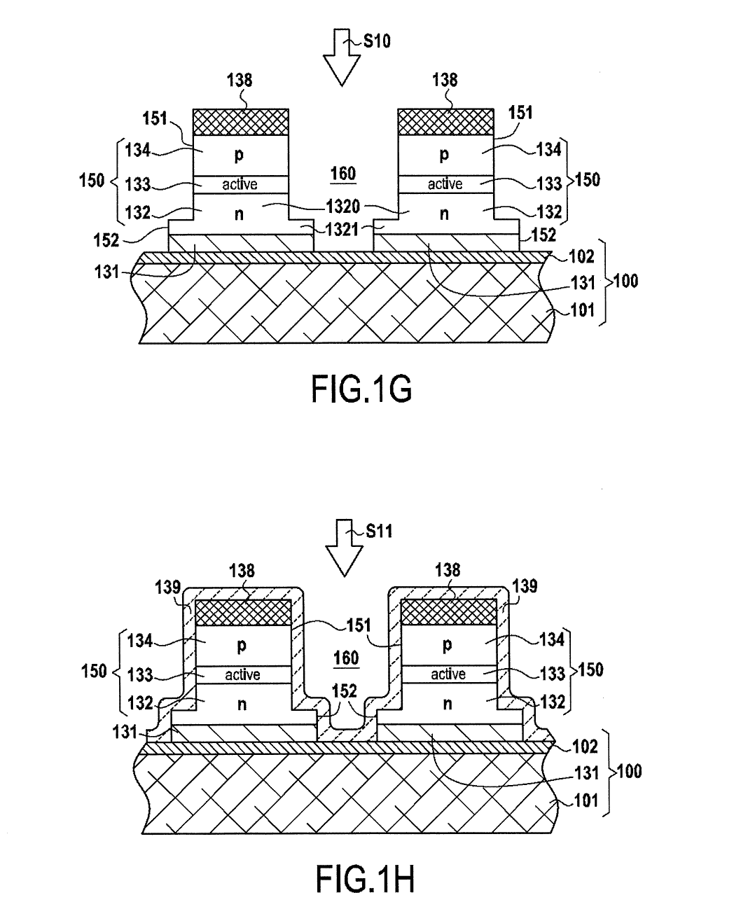

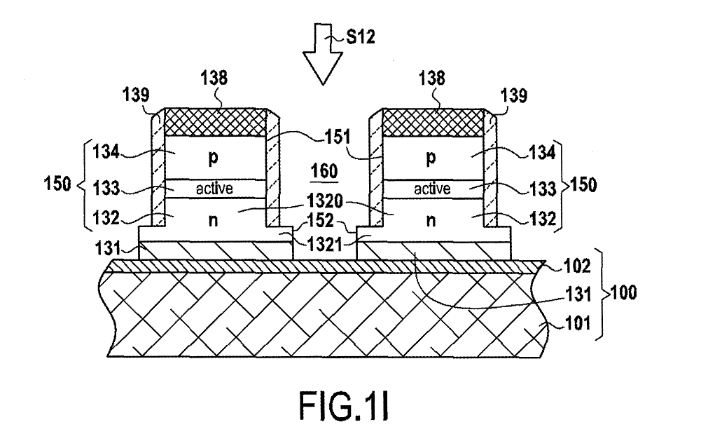

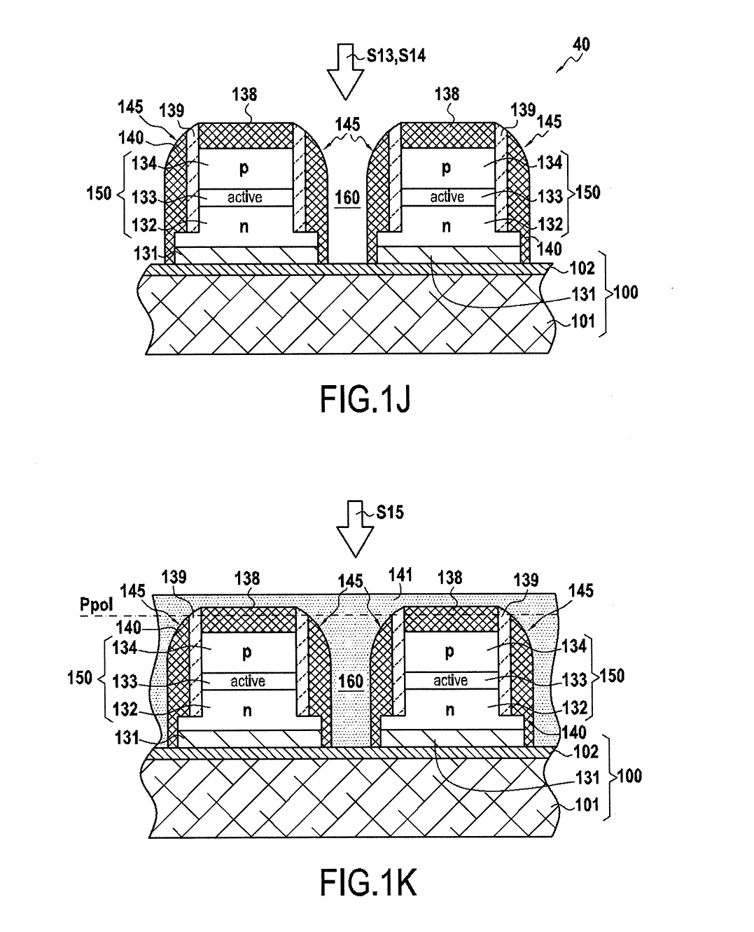

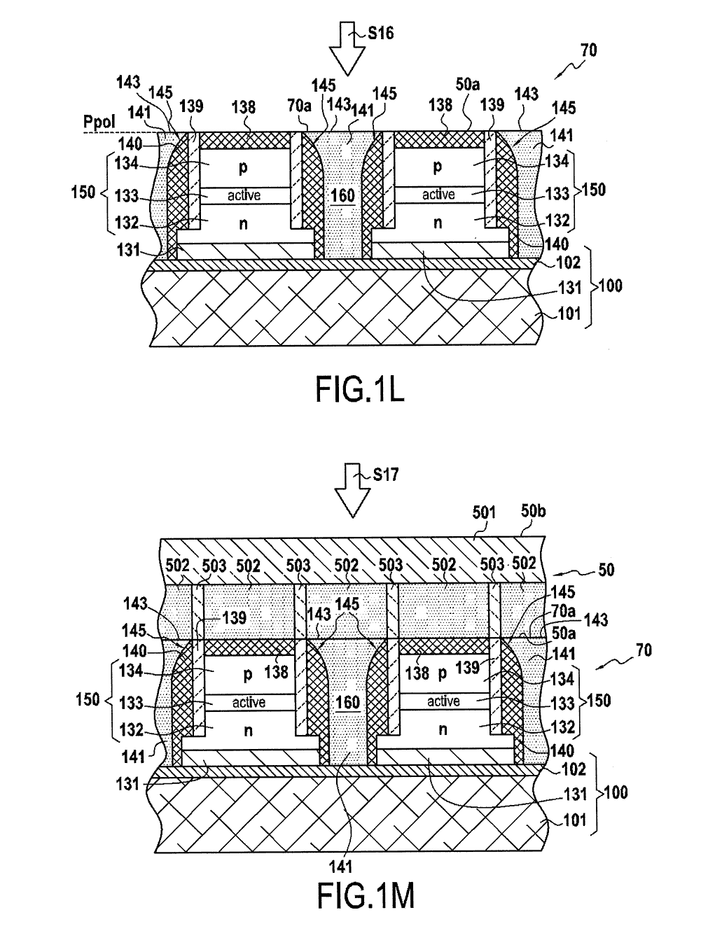

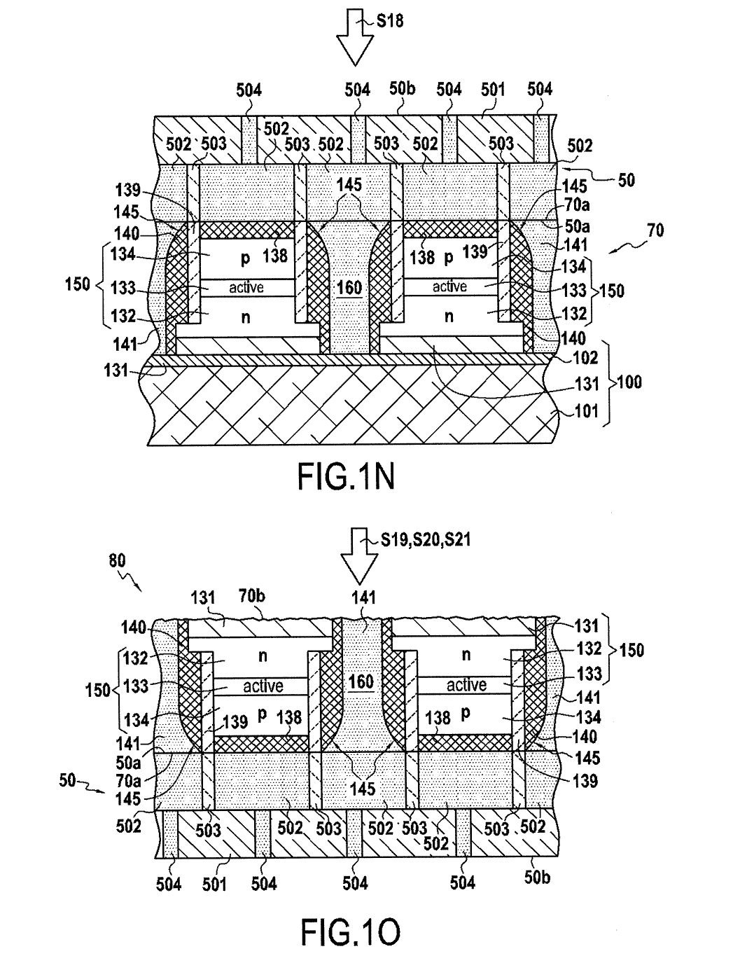

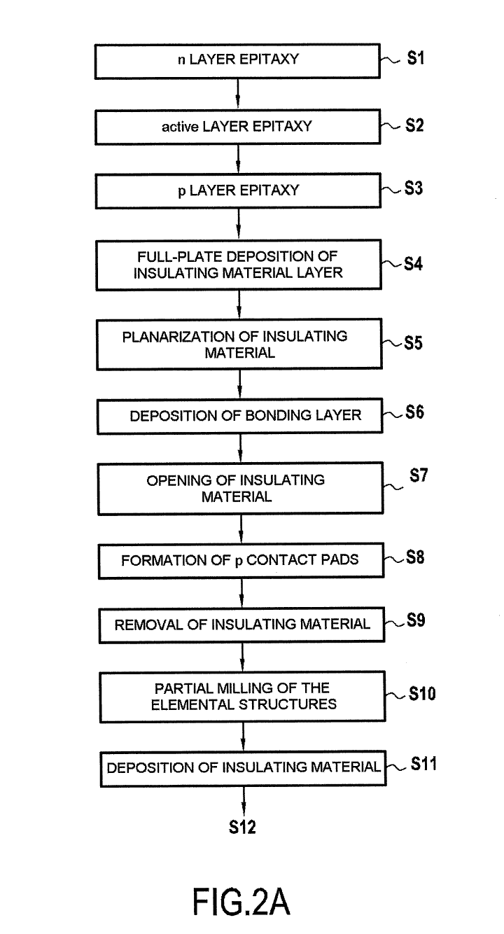

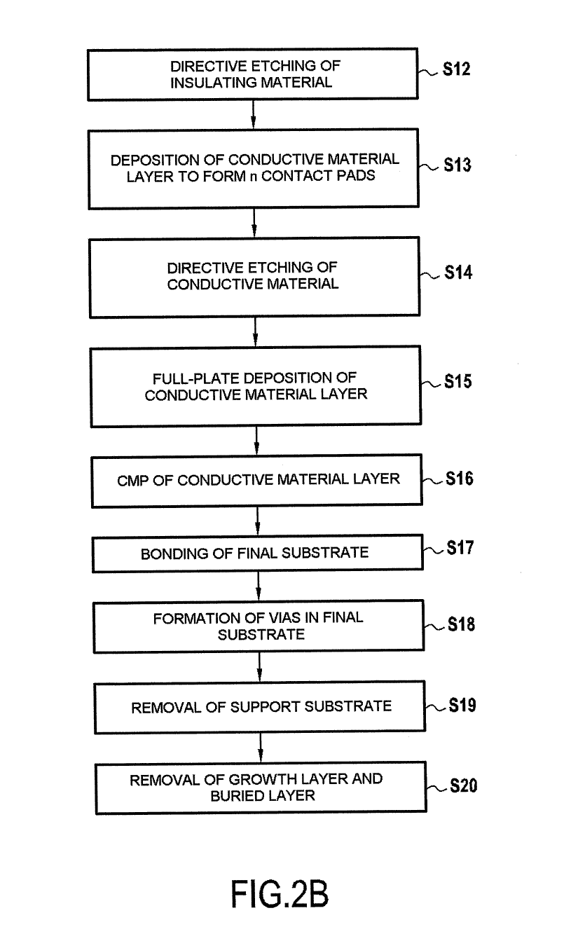

A method of collective manufacturing of LEDs is described in reference to FIGS. 1A to 1O and 2A and 2B.

In the example described here, the method is implemented from plate or composite growth substrate 100 comprising support substrate 101, buried layer 102 and growth islands 103 (FIG. 1A). Support substrate 101 consists here of sapphire. Substrate 101 can also be composed of a semiconductor material, such as, notably, silicon, silicon carbide or germanium. The buried layer is a bonding layer prepared here in SiO₂. Growth islands 103 are obtained from a growth layer of strained material, here an InGaN layer prepared, for example, by epitaxial growth on a GaN germ layer and transferred on support substrate 101 via buried layer 102.

Trenches 160 were made in the growth layer so as to delimit InGaN growth islands 131. These trenches also made it possible to relax the strained material of the growth layer. As a nonrestrictive example, each island 131 has here a square shape with sides 1 mm in length. The shape and dimensions of the islands, which define the shape and at least part of the dimensions of the final LEDs, can obviously be different, with the islands notably being able to have a circular shape.

The method begins with formation by epitaxy of n-type layer 132 (about 1 μm in thickness), active layer 133 (about 10 nm) and p-type layer 134 (between about 100 nm and 200 nm in thickness) on each island 131 by epitaxy (steps S1, S2, S3, FIG. 1B), these three layers forming on each island elemental LED structure 150. At this stage of the process, one has structure 10 in the form of a plate, which comprises a plurality of LED structures 150 on its upper surface, separated from each other by trenches 160.

The n- and p-type layers can be formed in the reverse order (p-type layer closest to islands 131) and include several layers of different compositions, thicknesses or dopant concentrations, comprising unintentionally doped layers.

Active layer 133 is a light-emitting layer that can be formed of a single thick or thin layer or of a plurality of layers of light-emitting quantum wells separated from each other by barrier layers.

Insulating material layer 136, here SiO₂, is deposited by plasma-enhanced chemical vapor deposition (PECVD) on the whole of the upper surface of structure 10 comprising elemental structures 150, layer 136 covering both the elemental structures 150 and trenches 160 (step S4, FIG. 1C). After deposition, insulating material layer 136 is planarized by chemical-mechanical polishing (CMP) or etching (step S5, FIG. 1C). SiO₂ layer 136 can also be formed by the well-known spin-on glass (SOG) technique, which consists of depositing, on the substrate in rotation on a spinner, a viscous SiO₂ precursor composition. With this deposition technique, the SiO₂ layer has a satisfactory surface quality that does not require post-deposition planarization.

According to an aspect of the disclosure, certain trenches 160 are not filled with insulating material 136 in order to facilitate cutting of the structure into a plurality of blocks, each comprising one or more LED structures. The trenches free of insulating material thus delimit cutting zones around the elemental structures.

Adhesion layer 135, for example, a titanium layer about 10 nm in thickness, can be formed on insulating material layer 160 in order to facilitate adhesion of the structure with certain metals that adhere with difficulty on SiO₂ (step S6, FIG. 1C).

Layers 135 and 136 are then opened, for example, by dry or wet selective chemical etching, on p-type layer 134 (step S7, FIG. 1D). In the example described here, openings 137 are formed in layer 136 on top of each p-type layer 134. To this end, use is made of an etching mask comprising a protective resin layer with openings (resin-free zones) delimiting the zones to be etched in the structure.

p-type contact pads 138 are formed in openings 137 by deposition in the latter of at least one conductive material (step S8, FIG. 1E). During deposition of the materials for contact pads 138, the mask used is preserved for etching openings 137. Once p-type contact pads 138 are formed, the protective resin of the etching mask is removed, which makes it possible to remove at the same time the constitutive materials of p-type contact pads 138 deposited beyond openings 137.

The layer forming p-type contact pads 138 can notably include:
a metal such as Ni, Pd or Pt with a thickness between 1 Å and 5 nm, in order to obtain a good resistivity and a good ohmic character,
a reflector, for example, in the form of a layer of Ag with a thickness of about 100 nm, in order to return to the emitting surface the photons leaving toward the opposite surface (i.e., those moving toward the p-type layer when the structure is transferred to the final substrate, the emitting surface thus being found on the side of n-type layer 132), and
a diffusion barrier, for example, in the form of a layer of WN or TiN with a thickness between 20 and 50 nm.

Formation of insulating material layer 136 on the whole of elemental structures 150 makes it possible to form collectively, i.e., in one operation for all structures 150, p-type contact pads 138.

At this stage of the process, one already has structure 20 in the form of a plate with a plurality of elemental structures 150, each provided with a p-type contact pad. Structure 20 can be cut out in a plurality of devices, each comprising one or more elemental structures 150, according to the final application envisaged, the remaining LED formation operations, such as formation of n-type contact pads, being carried out individually for each device cut out.

In the example described here, the method continues with the preparation of n-type contact pads comprising the opening or removal, for example, by chemical etching, of insulating material layer 136 present on the lateral surfaces of elemental structures 150 and in trenches 160 (step S9, FIG. 1F). At this stage of the process, one also has structure 30 in the form of a plate with a plurality of elemental structures 150, each provided with a p-type contact pad capable of forming alone or in multiples after cutting from the structure a plurality of devices.

One then proceeds with milling, for example, by chemical etching or dry etching, for example, reactive-ion etching (RIE), of a lateral portion of elemental structures 150 over a determined width from the lateral margin of each structure and to a determined depth in n-type layer 132 so as to form in each elemental structure 150 a milled portion 151 having reduced lateral dimensions (width, diameter, etc.), this milled portion comprising layers 134 and 133, as well as a first part 1320 of layer 132 in contact with active layer 133 (step S10, FIG. 1G). One thus forms in each elemental structure 150 a first portion 151 having reduced lateral dimensions (width, diameter, etc.) in relation to a second underlying portion 152 comprising the remaining part 1321 of unmilled layer 132.

After milling, one proceeds to full-plate deposition of thin insulating material layer 139, for example, SiO₂ (step S11, FIG. 1H). The thickness of the insulating material layer is limited so as to follow the contours of elemental LED structures 150 and trenches 160. This deposition is followed by directive dry etching that preferentially etches in the vertical direction so as to open insulating material layer 139 on the surface of p-type contact pads 138 and n-type layer 132 present on unmilled portion 152. After dry etching, layer 139 remains only on the sides of elemental structures 150 on milled portion 151 (step S12, FIG. 1I).

One then carries out deposition of conductive material layer 140, for example, Ti/Al/Ni, followed by directive dry etching that preferentially etches in the vertical direction so as to leave layer 140 remaining on the lateral walls of elemental structures 150 (steps S13 and S14, FIG. 1J). Conductive material layer 140 is in contact with the lateral wall of n-type layer 132 present on unmilled portion 152 of elemental structures 150 and is capable of forming n-type contact pads 145.

Thanks to the prior deposition of insulating material layer 139 for protecting the part of each elemental structure located above the unmilled portion of layer 132, the conductive material layer 140, intended to form n-type contact pads 145, can be deposited in an overall fashion (i.e., in a single operation) on the whole of the plate, which allows a collective preparation of n-type contact pads for each LED.

At this stage of the process, one has structure 40 in the form of a plate with a plurality of elemental structures 150, each provided with a p-type contact pad and an n-type contact pad, structure 40 being able to be cut into a plurality of devices, each comprising one or more elemental structures 150 according to the final application envisaged, the remaining LED formation operations being carried out individually for each device cut out.

In the example described here, conductive material layer 140 is present only on the lateral walls of elemental structures 150. According to a variant embodiment, the conductive material layer can entirely fill trenches 160. In the second case, the n-type layers 132 of the adjacent elemental structures are connected.

According to still another variant embodiment, the space present in the trenches between two portions of conductive material can be filled with an insulating material.

In all these variant embodiments, conductive material layer 140 is in contact with the entire lateral wall of the n-type layer 132 exposed on unmilled portion 152. One thus creates contact with a large surface, which makes it possible to significantly reduce electrical resistance at the n-type contact pad without really penalizing the integration density of the component. Indeed, since the n-type contact pad is prepared around the n-type layer, the width and the upper surface area of the final component increase little.

Furthermore, if layer 140 is deposited both on the lateral walls of n-type layers 132 and in trenches 160 (on the bottom of the trenches or filling the volume of the trenches), it is possible to put directly in parallel several adjacent elemental structures and to thus again minimize the electrical resistance of the n-type contact common to several structures.

When the conductive material layer is not continuous between two elemental structures, as is the case when it is etched as indicated above, it is possible during the final wiring operation to connect several elemental structures in series.

Conductive material layer 141, here copper, is deposited on the whole of the plate so as to cover the p-type contact pads 138 and n-type contact pads 145 (step S15, FIG. 1K). Conductive material layer 141 thus covers the whole of the elemental LED structures above contact pads 138 and fills trenches 160, thus connecting here n-type contact pads 145 of the adjacent elemental structures.

A bonding layer promoting semiconductor/metal adhesion, for example, Ta and/or TaN, is preferably deposited on p-type contact pads 138 and n-type contact pads 145 before deposition of layer 141.

Conductive material layer 141 is polished by chemical-mechanical polishing (CMP) to depth Ppol FIG. 1L) so as to expose p-type contact pads 138 and to form portions or n-type contact plugs 143 of conductive material layer 141 in contact with n-type contact pads 145 in order to allow contact on each of these pads (step S16, FIG. 1L). Contact pads 138 and 144 are separated from each other by insulating material layer 139. Polishing of conductive material layer 141, for example, is carried out until reaching at least the part of insulating material layer 139 present between p-type 138 and n-type 145 electrical contact pads so as to form structure 70 comprising individual portions 143 of conductive material layer 141, each of these individual portions 143 being in contact with one or more n-type electrical contact pads 145.

At this stage of the process, one has structure 70 having planar surface 70a compatible with direct bonding on a final or receiver substrate.

In the example described here, the method continues with bonding by molecular adhesion of structure 70 with final or receiver substrate 50 (step S17, FIG. 1M). As is well-known in its own right, the principle of bonding by molecular adhesion, also called direct bonding, is based on the bringing of two surfaces (here surfaces 70a and 50a of structure 70 and substrate 50) into direct contact, i.e., without the use of a specific material (adhesive, wax, solder, etc.). Such an operation requires that the surfaces to be bonded are sufficiently smooth and free of particles or contamination and that they are brought sufficiently close to make it possible to initiate contact, typically at a distance of less than a few nanometers. In this case, the attractive forces between the two surfaces are great enough to cause molecular adhesion (bonding induced by the sum of the attractive forces (van der Waals forces) of the electron interactions between the atoms or molecules of the two surfaces to be bonded).

However, structure 70 and final substrate 50 can also be assembled by other types of bonding, such as anodic bonding, metallic bonding, or with adhesive.

Final substrate 50 makes it possible to at least ensure good mechanical support for the final LED devices, as well as access to the n- and p-type contact pads. In the example described at present, final substrate 50 is formed of a plate 501 that comprises on the side of the substrate's bonding surface 50a, copper contact pads 502 insulated from each other by portions of insulating material 503, for example, SiN. Each contact pad 502 was formed at a location in alignment with at least part of p-type contact pad 138 or part of n-type contact plug 143 exposed on planar surface 70a of structure 70 (FIG. 1M). Plate 501 can be composed notably of alumina, or of polycrystalline AlN, a good thermal conductor, or of silicon.

In this case, p-type contact pads 138 and n-type contact plugs 143 of structure 70 are accessed from surface 50b opposite bonding surface 50a of final substrate 50 by forming vertical electronic connections 504, also called vias, for example, of copper, through plate 501, each of these vertical connections emerging at a contact pad 502 (step S18, FIG. 1N). In the case of a plate 501 of silicon, the internal surface of the vias will be insulated beforehand in accordance with the well-known through-silicon via (TSV) method. Electronic connections 504 and their optional internal insulation are prepared, preferably before bonding final substrate 50.

According to a variant embodiment, the final substrate can be formed of a solid plate, for example, silicon or AlN, on the bonding surface from which have been cut a plurality of cavities at locations in alignment with the parts exposed on planar surface 70a of structure 70 of p-type contact pads 138 and n-type contact plugs 143, the cavities being filled with a conductive material, for example, copper. Once the final substrate is bonded to structure 70, the latter is thinned to uncover the conductive material present in the cavities so as to form vertical electrical connections, each respectively in contact with a p-type contact pad 138 or n-type contact plug 143 and accessible by the back of the final substrate.

In the case where the final substrate material allows it, for example, in the case where the final substrate is formed of a silicon plate or comprises a layer of silicon, electronic circuits intended to function with the LED devices can be formed beforehand and connected to p-type contact pads 138 and n-type contact plugs 143 by vertical electronic connections formed in the final substrate. Among the electronic circuits that can be envisaged, particular mention may be made of passive regulation devices (protection diode, resistance for ESD, condenser, etc.) and active regulation devices (current regulator).

The final substrate can also include electronic interconnection circuits allowing the preparation of LED devices comprising several elemental LED structures connected in series or in parallel.

According to another variant embodiment, surface 70a of structure 70 can be covered with a layer of SiO₂ planarized by chemical-mechanical polishing. The final substrate is in this case composed of a plate of virgin silicon or of insulating substrate (alumina or MN, for example). If the bonding surface of the final substrate is too rough for bonding by molecular adhesion (typically >0.3 nm RMS for a 5×5 μm surface scan), a layer of SiO₂ can also be deposited and planarized. The two surfaces thus prepared are bonded together by molecular adhesion. Annealing can be carried out to strengthen the bond. The final substrate can then be thinned (to 100 μm, for example) to allow the preparation of vertical electrical connections or vias in contact with the p- and n-type contact pads of LEDs structure 70. With this variant embodiment, one is freed from the problems of alignment between the contact pads of the LEDs structure and the electrical connections or vias of the final substrate since the latter are prepared after bonding of the LEDs structure with the final substrate.

Once final substrate 50 and structure 70 are assembled, support substrate 101 is removed, for example, by the well-known laser lift-off technique, notably in the case of a sapphire substrate, or by chemical etching (step S19, FIG. 1O). In the particular case of an InGaN support substrate, its removal by laser lift-off can be adapted by inserting layers facilitating detachment of the substrate by this technique. In the case of removal by chemical etching, barrier layers can also be inserted to preserve the remainder of the LEDs structure. In the case of removal by laser lift-off or another nondestructive technique, the support substrate can be reused.

After removal of support substrate 101, carried out here by laser lift-off, buried layer 102 and growth islands 131 are removed, for example, by chemical etching (step S20, FIG. 1O).

One obtains, at this stage of the process, structure 80 from which can be cut out LED devices, each formed of one or more elemental structures wired and provided with a substrate equipped with n- and p-type connections disposed on one surface of the latter.

Still collectively, uncovered rear surface 70b of LEDs structure 70 can be etched in order to remove any residues remaining from support substrate 101, buried layer 102, or growth islands 131 and can be structured to increase the extraction of light therefrom (step S21, FIG. 1O). Notably, etching can be carried out by reactive plasma etching (chlorinated or fluorinated) or by UV-assisted chemical (PEC) etching.

In the case of formation of white-light LED devices, a layer of luminophoric material, capable of converting light emitted by the devices into white light, can be deposited on surface 70b of LEDs structure 70, for example, by applying a liquid phosphorus-based composition to surface 70b of structure 70 followed by annealing to evaporate the dispersion solvent (spin-on glass).

Furthermore, the LED devices can be provided with microstructures, such as Fresnel lenses, for example, by nano- or micro-printing microstructures on surface 70b of structure 70.

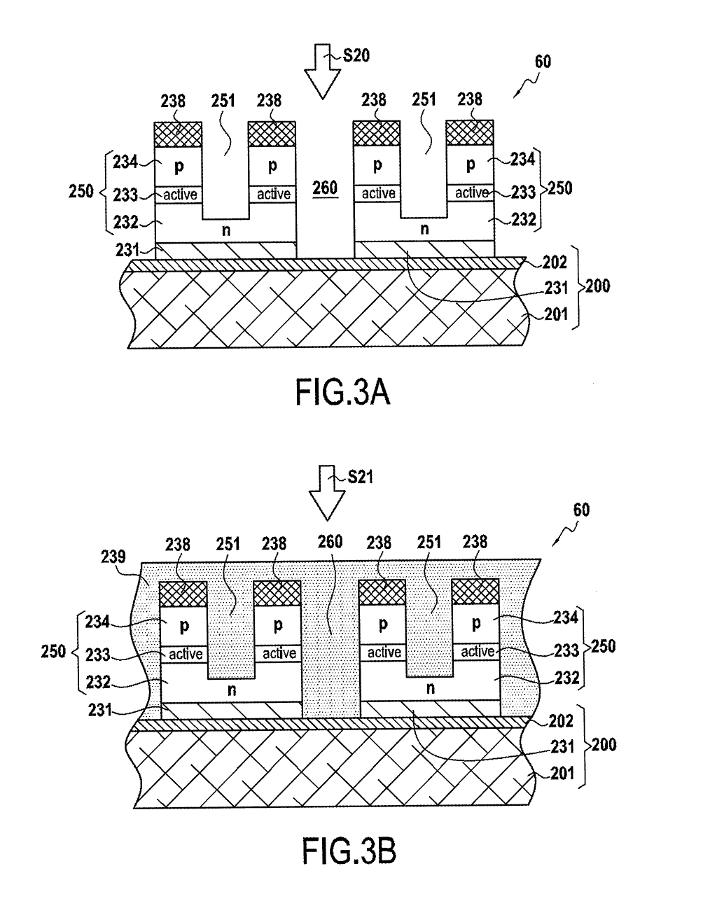

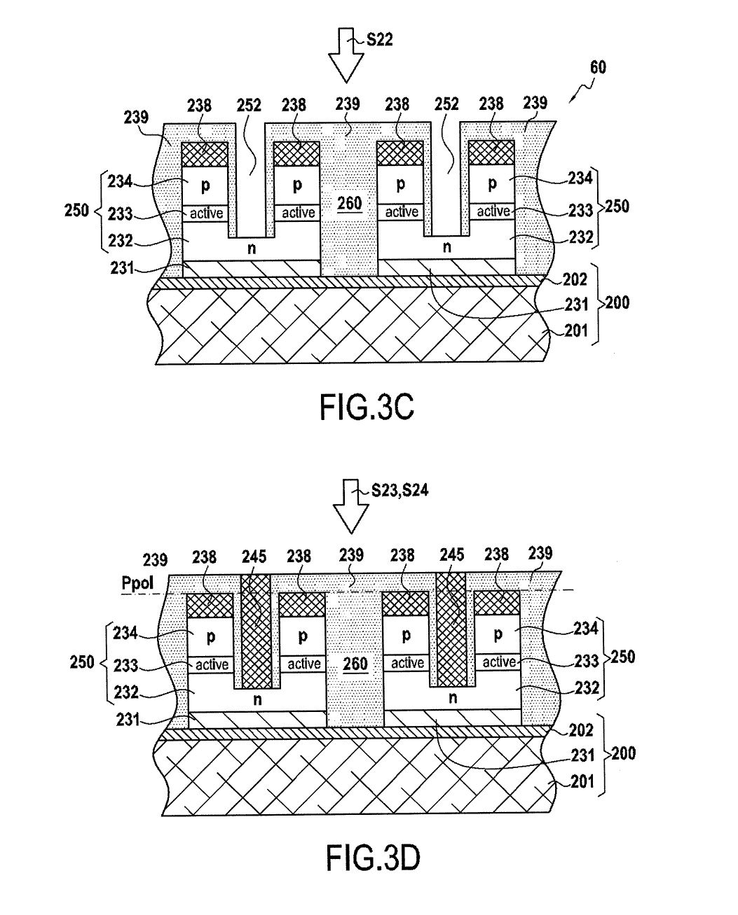

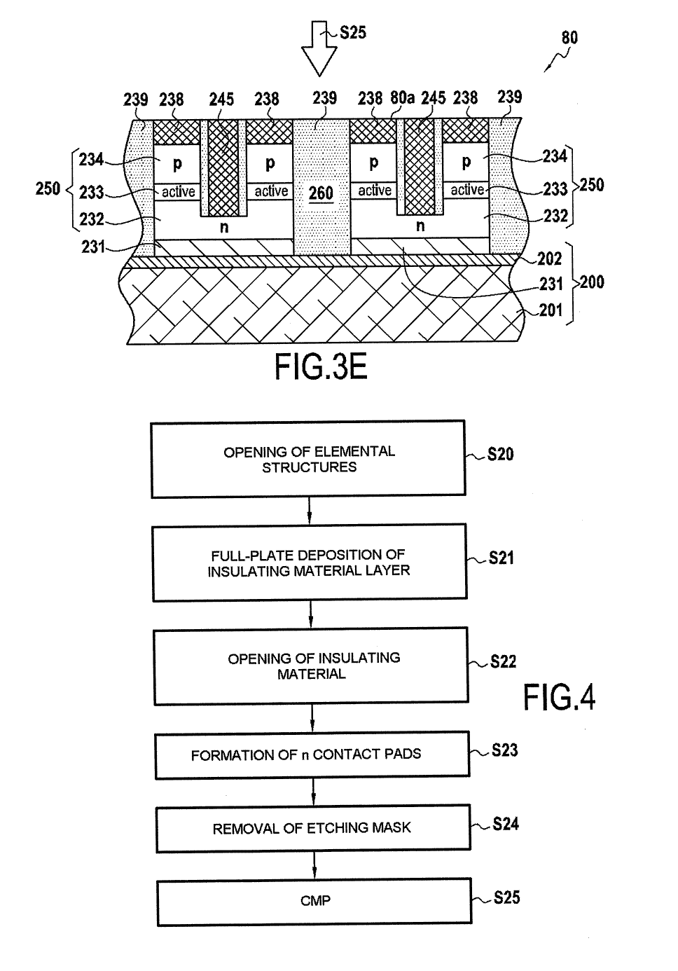

According to a variant embodiment of the inventive method, n-type contact pads are formed inside the elemental LED structures. This variant embodiment is implemented from a structure 60 identical to structure 30 presented in FIG. 1F and obtained after steps S1 to S9 described above. More precisely, as illustrated in FIG. 3A, structure 60 comprises, as described above, a plate or composite growth substrate 200 comprising a support substrate 201, buried layer 202 and growth islands 231 separated by trenches 260 and on which have been prepared elemental structures 250 comprising an n-type layer 232, active layer 233 and p-type layer 234. p-type contact pads 238 were further formed on p-type layers 234 as described above.

In accordance with this variant embodiment, a central opening 251 is made in each elemental structure 250 from p-type contact pad 138 through to n-type layer 232 (step S20, FIG. 3A). Openings 251 can notably be prepared by chemical etching or dry etching, for example, reactive-ion etching (RIE).

Insulating material layer 239, for example, SiO₂, is deposited by plasma-enhanced chemical vapor deposition (PECVD) on the whole of the upper surface of structure 200 comprising elemental structures 250, layer 239 covering both elemental structures 250 and trenches 260 (step S21, FIG. 3B).

Layer 239 is then opened, for example, by dry or wet selective chemical etching, so as to create central openings 252 of the same depth as openings 251 but over a narrower width than the latter (step S22, FIG. 3C). To this end, use is made of an etching mask comprising a protective resin layer with openings delimiting the zones to be etched in the structure, here openings 252. Openings 252 being narrower than openings 251, a portion of insulating material layer 239 remains on the sides of the p-type contact pads and of layers 234, 233 and 232 exposed in openings 251 (FIG. 3C).

n-type contact pads 245 are formed in openings 252 by deposition in the latter of at least one conductive material, for example, Ti/Al/Ni, that is in contact with n-type layer 232 exposed at the bottom of openings 252 (step S23, FIG. 3D). During deposition of materials for n-type contact pads 245, the mask used is preserved for etching openings 252. Once contact pads 245 are formed, the protective resin of the etching mask is removed, which makes it possible to remove at the same time the constitutive materials of n-type contact pads 245 deposited beyond openings 252 (step S24, FIG. 3D).

Insulating material layer 239 and n-type contact pads 245 are polished by chemical-mechanical polishing (CMP) to depth Ppol (FIG. 3D) so as to expose p-type contact pads 238 and n-type contact pads 245 in order to allow a contact plug on each of these pads (step S25, FIG. 3E). Contact pads 238 and 245 are separated from each other by insulating material layer 239.

At this stage of the process, one has structure 80 with planar surface 80a compatible with direct bonding with a final or receiver substrate.

The method then continues in the same way as described above, i.e., by repeating steps S17 to S20 described above in reference to FIGS. 1M to 1O.

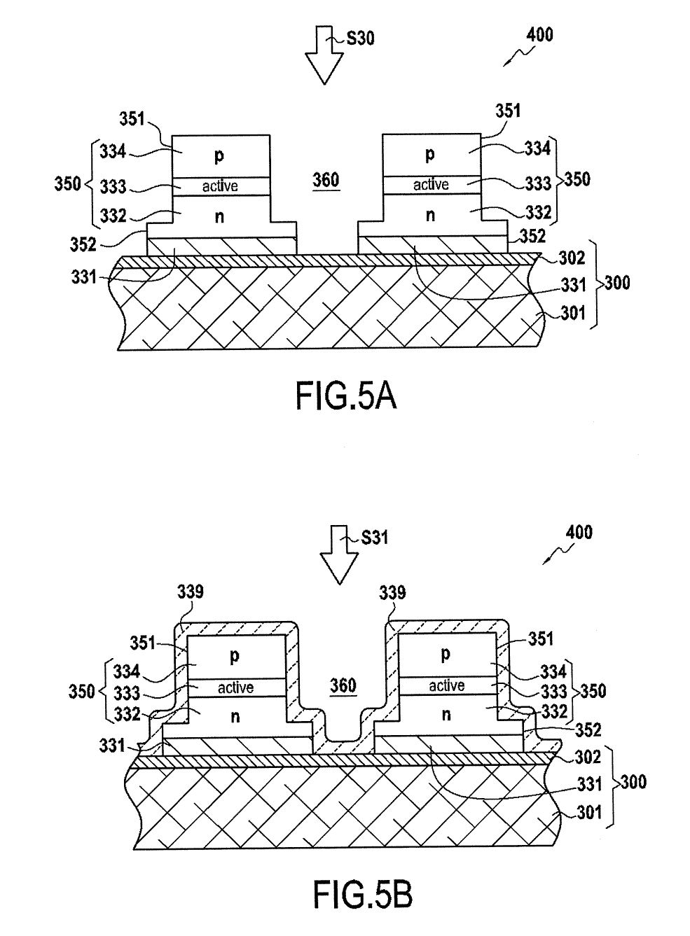

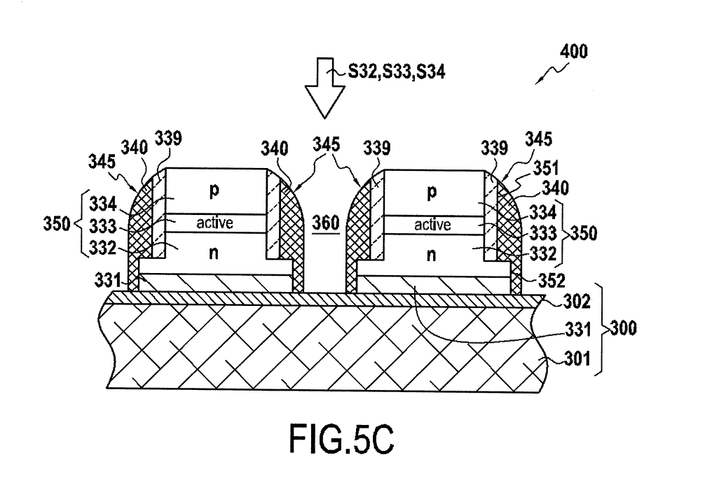

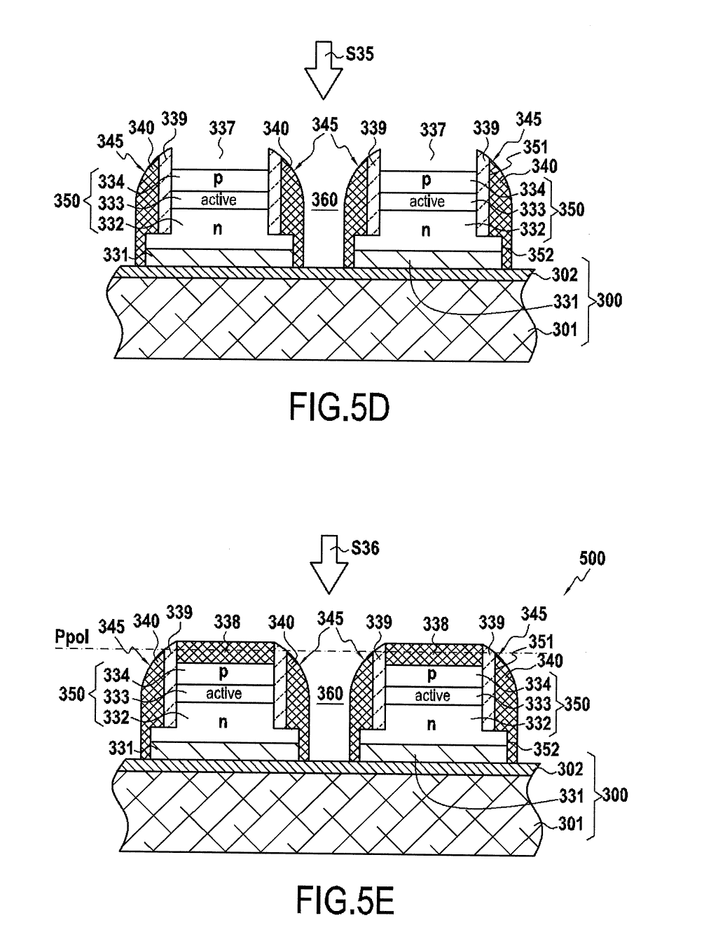

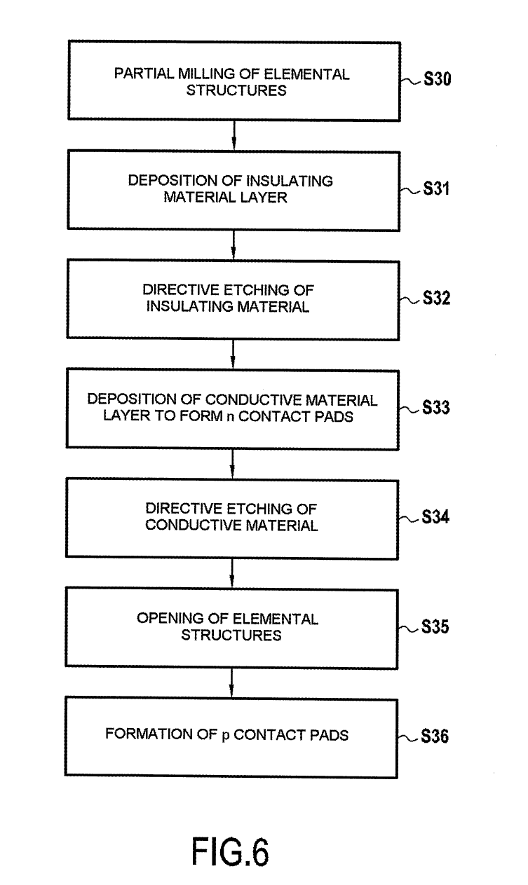

According to another variant embodiment of the disclosed method described in reference to FIGS. 5A to 5E and 6, p-type contact pads are formed after n-type contact pads. This variant embodiment is implemented from a structure 400 identical to the structure presented in FIG. 1G but without p-type contact pads, structure 400 being obtained after steps forming elemental structures 350 separated by trenches 360 and comprising n-type layer 332, active layer 333 and p-type layer 334 prepared under the same conditions as steps S1, S2 and S3 described above, and after a milling step carried out under the same conditions as step S10 described above. Milling, for example, is carried out by chemical etching or dry etching of a lateral portion of elemental structures 350 over a determined width and to a determined depth in n-type layer 332 so as to form in each elemental structure 350, on the one hand, milled portion 351 having reduced lateral dimensions and comprising layers 334 and 333 as well as part of layer 332 and, on the other hand, an underlying portion 352 comprising the remainder of unmilled layer 332 (step S30, FIG. 5A).

After milling, one proceeds to full-plate deposition of thin insulating material layer 339, for example, SiO₂ (step S31, FIG. 5B) such as, for example, described above in reference to step S11. This deposition is followed by directive dry etching (similar to step S12 described above) that preferentially etches in the vertical direction so as to open insulating material layer 339 on the surface of p-type contact pads 338 and n-type layer 332 present on unmilled portion 352. After dry etching, layer 339 remains only on the sides of elemental structures 350 on milled portion 351 (step S32, FIG. 5C).

One then carries out deposition of conductive material layer 340, for example, Ti/Al/Ni, followed by directive dry etching that preferentially etches in the vertical direction so as to leave layer 340 remaining on the lateral walls of elemental structures 150 (steps S33 and S34, FIG. 5C). These steps S33 and S34 are carried out under the same conditions as steps S13 and S14, respectively. Conductive material layer 340 is in contact with the lateral wall of n-type layer 332 present on unmilled portion 352 of elemental structures 350 and is capable of forming n-type contact pads 345.

P-type layers 334 are then opened, for example, by dry or wet selective chemical etching, over a limited depth (step S35, FIG. 5D). To this end, use is made of an etching mask comprising a protective resin layer with openings delimiting the zones to be etched in the structure, namely openings 337.

p-type contact pads 338 are formed in openings 337 by deposition in the latter of at least one conductive material (step S36, FIG. 5E). During deposition of the materials for contact pads 338, the mask used is preserved for etching openings 337. Once p-type contact pads 338 are formed, the protective resin of the etching mask is removed, which makes it possible to remove at the same time the constitutive materials of p-type contact pads 338 deposited beyond openings 337.

At this stage of the process, one has structure 500 in the form of a plate with a plurality of elemental structures 350, each provided with a p-type contact pad and an n-type contact pad, structure 500 being able to be cut out in a plurality of devices, each comprising one or more elemental structures 350 according to the final application envisaged, the remaining LED formation operations being carried out individually for each device cut out.

The method then continues in the same way as described above, i.e., by repeating steps S15 to S21 described above in reference to FIGS. 1K to 1O.

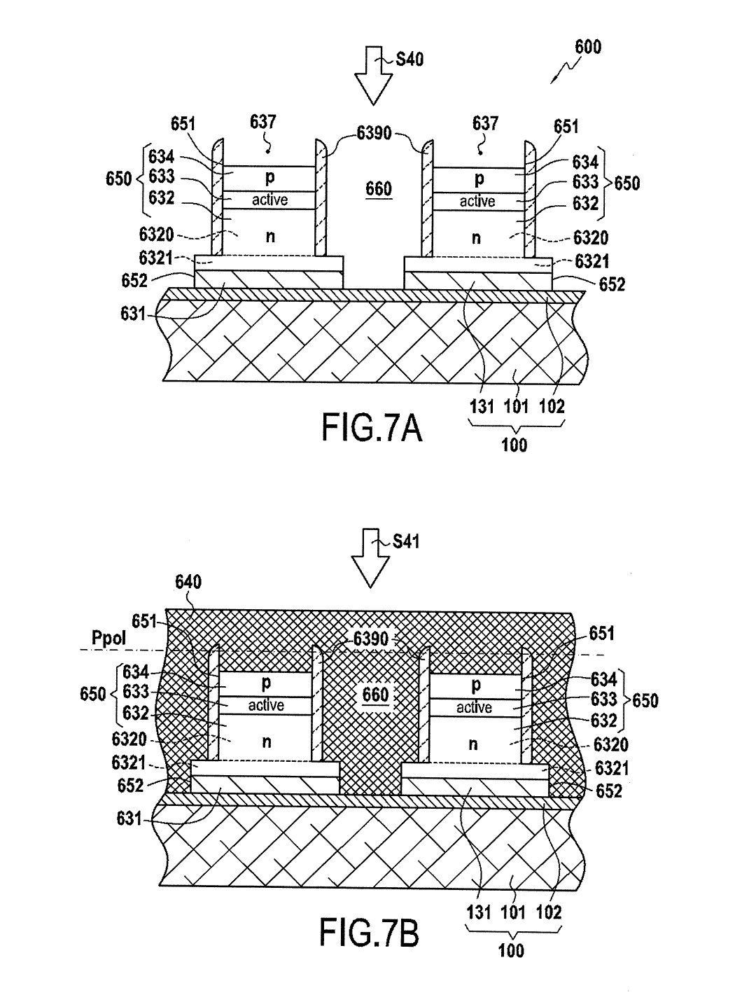

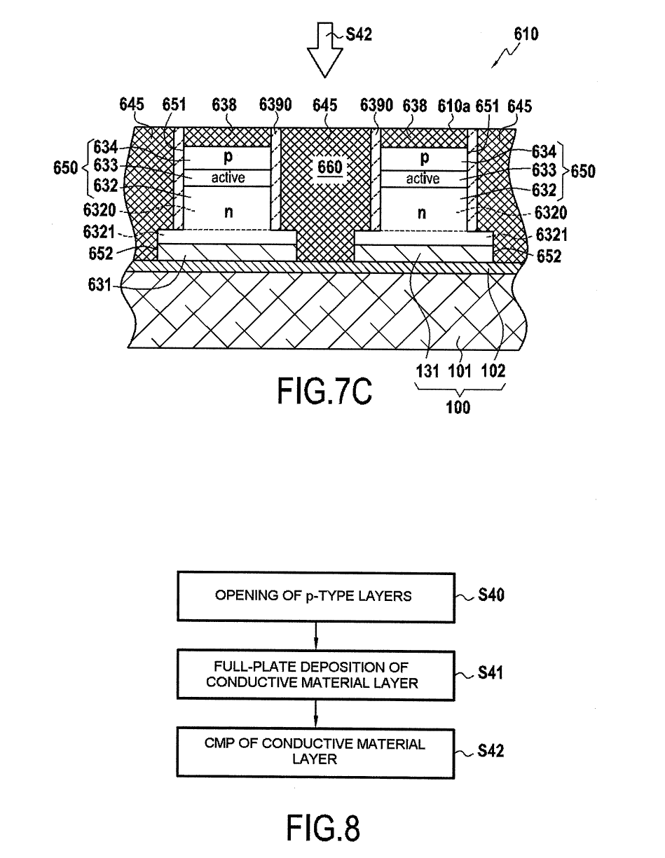

According to another variant embodiment of the disclosed method described in reference to FIGS. 7A to 7C and 8, the n- and p-type contact pads are formed simultaneously. This variant embodiment is implemented from a structure 600 identical to the structure described above at the conclusion of step S32, i.e., after:
steps forming elemental LED structures 650 separated by trenches 660 and comprising n-type layer 632, active layer 633 and p-type layer 634 carried out under the same conditions as steps S1, S2 and S3 described above,
a step carried out under the same conditions as step S10 described above and making it possible to form in each elemental LED structure 650 a first portion 651 comprising p-type layer 634, active layer 633 and a first part 6320 of the n-type layer in contact with active layer 633 and having reduced lateral dimensions (width, diameter, etc.) in relation to a second underlying portion 652 comprising second part 6321 of unmilled n-type layer 632,
a step similar to step S11 described above of full-plate deposition of an insulating material layer, for example, SiO₂, having a limited thickness so as to follow the contours of elemental LED structures 650 and trenches 660, and
a step similar to step S12 described above of directive dry etching that preferentially etches in the vertical direction so as to leave remaining only portion 6390 of the insulating material layer on the sides of elemental structures 650 on first portion 651 of reduced lateral dimensions.

In this variant embodiment, p-type layers 634 are then opened, for example, by dry or wet selective chemical etching, to a determined depth (step S40, FIG. 7A). To this end, use is made of an etching mask comprising a protective resin layer with openings delimiting the zones to be etched in the structure, here openings 637.

One then carries out full-plate deposition of conductive material layer 640, which covers the whole of elemental structures 650 and trenches 660 while filling openings 637 (step S41, FIG. 7B).

Conductive material layer 640 is polished by chemical-mechanical polishing (CMP) to depth Ppol (FIG. 7B) so as to form p-type contact pads 638 and n-type contact pads 645 separated from each other by portions 6390 of insulating material (step S42, FIG. 7C).

At this stage of the process, one has structure 610 in the form of a plate with a plurality of elemental structures 650, each provided with a p-type contact pad and an n-type contact pad, structure 610 having planar surface 610a compatible with bonding by molecular adhesion on a final or receiver substrate.

1. A method of collective manufacturing of light-emitting diode (LED) devices comprising formation on a surface of a first substrate of a plurality of elemental LED structures, each comprising at least one n-type layer, an active layer and a p-type layer, the elemental LED structures being spaced apart from each other on the first substrate by trenches, the method further comprising:
reduction of the lateral dimensions of the p-type layer, the active layer and a first part of the n-type layer in contact with the active layer, the n-type layer having a second part with lateral dimensions larger than the first part of the n-type layer;
deposition of an insulating material layer on at least each elemental structure;
formation of a portion of insulating material on the sides of the p-type layer, the active layer and the first part of the n-type layer;
formation of n-type electrical contact pads on at least the whole of the second part of the exposed n-type layer;
formation of p-type electrical contact pads before or after the lateral dimension reduction step;
deposition of a conductive material layer on the whole of the surface of the first substrate comprising the elemental LED structures and polishing the conductive material layer, the polishing being carried out until reaching at least the part of the insulating material layer present between the p- and n-type electrical contact pads so as to form a structure comprising individual portions of the conductive material layer, each individual portion being in contact with one or more n-type electrical contact pads; and
bonding by molecular adhesion of a second substrate on the polished surface of the structure.

2. The method according to claim 1, wherein the insulating material layer is further deposited in part of the trenches present between the elemental LED structures, the trenches free of insulating material delimiting cutting zones around the elemental LED structures.

3. The method according to claim 1, wherein each elemental LED structure is formed on an island of relaxed or partially relaxed material.

4. The method according to claim 3, wherein the relaxed or partially relaxed material is InGaN.

5. The method according to claim 1, further comprising, after the bonding of the second substrate, removal of the first substrate.

6. The method according to claim 5, further comprising deposition of a light-converting material layer on the surface of the elemental LED structures exposed after removal of the first substrate.

7. The method according to claim 5, further comprising formation of microstructures on the surface of the elemental LED structures exposed after removal of the first substrate.

8. The method according to claim 1, wherein the second substrate comprises on its bonding surface a plurality of electrical contact pads disposed at positions in alignment with the individual portions of the conductive material layer or with the p-type contact pads.

9. The method according to claim 1, wherein formation of the n-type contact pads comprises deposition of a conductive material layer of determined thickness on the whole of the surface of the first substrate comprising the elemental LED structures.

10. The method according to claim 9, further comprising, after deposition of the conductive material layer, directive etching of the conductive material layer so as to leave remaining portions of the conductive material layer on the lateral walls of the elemental structures, the portions forming the n-type contact pads.

11. The method according to claim 10, further comprising, after the selective etching step, formation of openings to a limited depth in the p-type layer of each elemental LED structure and filling of these openings with a conductive material so as to form a p-type contact pad.

12. A structure for the collective manufacture of light-emitting diode (LED) devices comprising a first substrate including on a surface a plurality of elemental LED structures, each comprising at least one n-type layer, an active layer and a p-type layer, the elemental structures being spaced apart from each other on the first substrate by trenches,
wherein each elemental LED structure comprises:
a first part comprising the p-type layer, the active layer and a first part of the n-type layer in contact with the active layer and a second part comprising a second part of the n-type layer, the first part of each elemental LED structure having lateral dimensions less than the second part of each elemental LED structure;
a part of insulating material on the sides of the p-type layer, the active layer and the first part of the n-type layer;
an n-type electrical contact pad on at least the whole of the second part of the exposed n-type layer; and
p-type electrical contact pads;
the structure further comprising, on its side opposite that comprising the first substrate, a planar surface comprising individual portions of conductive material, each respectively in contact with an n-type electrical contact pad, the individual portions of the layers of conductive material being separated by portions of the insulating material layer,
a second substrate being bonded on the planar surface of the structure.

13. The structure according to claim 12, wherein the second substrate comprises on its surface bonded to the structure a series of contact pads separated from each other by portions of insulating material, the pads of the series of contact pads being connected with the n- and p-type electrical contact pads of the elemental structures.

14. The structure according to claim 12, further comprising a light-converting material layer on the n-type layer of the elemental LED structures.

15. The structure according to claim 12, further comprising microstructures on the n-type layer of the elemental LED structures.

16. The structure according to claim 12, wherein two or more of the elemental LED structures are electrically connected in parallel.

17. The structure according to claim 12, wherein two or more of the elemental LED structures are electrically connected in series.

18. The structure according to claim 12, wherein the n-type layers of two or more elemental LED structures are directly electrically coupled to one another by conductive material disposed in trenches between the two or more elemental LED structures.

19. The structure according to claim 12, wherein the conductive material is in contact with an entire lateral wall of each of the second parts of the n-type layers of the elemental LED structures.

20. The structure according to claim 12, wherein the second substrate is directly molecularly bonded on the planar surface of the structure.
